(19) United States
(12) Patent Application Publication
(10) Pub. No.: US 2008/0173903 A1
(43) Pub. Date: Jul. 24, 2008

(54) SOLID-STATE IMAGE PICKUP ELEMENT

(75) Inventors: Fumikazu Imai, Minami-Ashigara-Shi (JP); Akihiro Anzai, Minami-Ashigara-Shi (JP)

Correspondence Address: BIRCH STEWART KOLASCH & BIRCH, PO BOX 747, FALLS CHURCH, VA, 22040-0747, US

(73) Assignee: FUJIFILM Corporation, Tokyo (JP)

(21) Appl. No.: 11/966,845

(22) Filed: Dec. 28, 2007

(30) Foreign Application Priority Data
Dec. 28, 2006 (JP) 2006-355828
Feb. 2, 2007 (JP) 2007-024685
Mar. 30, 2007 (JP) 2007-095568

(51) Int. Cl. H01L 31/0232

(52) U.S. Cl. 257/231; 257/432; 257/E31.119; 257/E31.127

(57) ABSTRACT

A solid-state image pickup element equipped with a film stack, a color filter, and a microlens on a semiconductor substrate equipped with a light receiving section, comprises a first film with a high refractive index and a second film with a low refractive index adjacently arranged on the semiconductor substrate in this order viewing from the semiconductor substrate side, each of which has at least one layer respectively. Thereby it makes possible to reduce the loss of incident light, and to achieve the enhancement in photoelectric conversion efficiency.

### BACKGROUND OF THE INVENTION

1. Field of the Invention

The present invention relates to a solid-state image pickup element, and in particular, relates to a solid-state image pickup element which has enhanced photoelectric conversion efficiency by enhancing an anti-reflection efficiency.

2. Description of the Related Art

Now, solid-state image pickup elements are used for optical devices such as digital still cameras and video cameras. Generally, a solid-state image pickup element is equipped with a semiconductor substrate, a light receiving section formed in the semiconductor substrate, and a signal transfer section which is formed on the semiconductor substrate and transfers a signal which is generated in the light receiving section. Furthermore, a color filter and a microlens are formed in an upper aperture section above the light receiving section. Incident light into the solid-state image pickup element is radiated on the light receiving section through the macro lens and color filter, and is given photo-electric conversion by the light receiving section. A signal generated in the light receiving section by photo-electric conversion is transferred outside through the signal transfer section.

In recent years, to achieve miniaturization and a higher pixel count of optical devices, miniaturization and a higher count of a solid-state image pickup element has been advancing quickly. There has been problem that an area of a light receiving section decreases and sensitivity decreases with the miniaturization and high pixel count of a solid-state image pickup element. In addition, there has been another problem that, with the decrease of the area of the light receiving section, an aspect ratio which is a ratio of width of the light receiving section to height from the light receiving section to the aperture section becomes high, and hence, the sensitivity further decreases. Therefore, enhancement in photoelectric conversion efficiency in a light receiving section is desired.

In order to solve these problems, in Japanese Patent Application Laid-Open No. 2005-268634, it is proposed to reduce a loss of incident light to achieve enhancement in the photoelectric conversion efficiency by stacking a low refractive index film which is constructed of silicon oxide on a light receiving section, and a high refractive index fihm which is constructed of silicon nitride which has a refractive index higher than the silicon oxide.

In addition, in a solid-state image pickup element, in order to prevent a drop of sensitivity of the light receiving section, an anti-reflection film covering the light receiving section is generally formed. For example, in Japanese Patent Application Laid-Open No. 2000-12817, it is disclosed to deposit an anti-oxidation film, which is constructed of a silicon nitride film, on a semiconductor substrate by an LPCVD (Law Pressure Chemical Vapor Deposition) method. Furthermore, in Japanese Patent Application Laid-Open No. 2005-33110, it is disclosed to form an anti-reflection film, which is constructed of a silicon nitride film, by a sputtering method so as to cover a part of a light-receiving element formed on a semiconductor substrate.

However, since a prevention effect of reflected light was not sufficient in the conventional stacked structure of a low refractive index film and a high refractive index film, enhancement in photoelectric conversion efficiency is remained as a problem.

In addition, in the LPCVD method or sputtering method, since an anti-reflection film was formed in vacuum process, an expensive facility and the like were necessary. Therefore, there has been a problem that it was hard to produce a solid-state image pickup element inexpensively.

### SUMMARY OF THE INVENTION

In order to solve the problems, the present invention aims at providing a solid-state image pickup element which can enhance an anti-reflection efficiency to prevent a loss of incident light, and to achieve enhancement in photoelectric conversion efficiency.

In another aspect, so as to solve the problems, the present invention aims at providing a solid-state image pickup element equipped with an anti-reflection film, which is produced by a comparatively inexpensive and simple method, and its production method.

In order to achieve the object, a solid-state image pickup element according to an aspect of the present invention including a semiconductor substrate, a light receiving section formed on the semiconductor substrate, and a signal transfer section which is formed on the semiconductor substrate and transfers a signal generated in the light receiving section, comprises a first film with a high refractive index and a second film with a low refractive index adjacently arranged in this order viewing from the semiconductor side, each of which has at least one layer.

By adjacently arranging the first film with a high refractive index and the second film with a low refractive index, each of which has at least one layer respectively, on the semiconductor substrate in this order from a semiconductor substrate side, the first film and second film have an anti-reflection function, thereby, it becomes possible to reduce the loss of incident light, and to achieve the enhancement in photoelectric conversion efficiency.

In the solid-state image pickup element according to an aspect of the present invention, it is preferable that a refractive index of the first film is 1.6 to 2.5 inclusive, and a refractive index of the second film is 1.3 to 1.9 inclusive.

In the solid-state image pickup element according to an aspect of the present invention, the semiconductor substrate may comprise a silicon oxide film, and it is preferable that film thickness of the silicon oxide film is 100 nm or less. This is because it is preferable that the silicon oxide film is as thin as possible in the case that the silicon oxide film is formed on the semiconductor substrate, since the silicon oxide film obstructs the reduction of reflectance reduction.

In the solid-state image pickup element according to an aspect of the present invention, it is preferable that the first film includes one material selected from a group comprising silicon nitride, cerium oxide, zirconium oxide, yttrium oxide, hafnium oxide, tantalum oxide, titanium nitride, and titanium oxide.

In the solid-state image pickup element according to an aspect of the present invention, it is preferable that the second film includes one material selected from a group comprising magnesium fluoride, silicon oxide, silicon nitride, nitride oxide silicon, and silicon nitride.

In the solid-state image pickup element according to an aspect of the present invention, it is preferable that film thickness of the first film is 10 nm to 100 nm inclusive.

In the solid-state image pickup element according to an aspect of the present invention, it is preferable that film thickness of the second film is 30 nm to 200 nm inclusive.

According to an aspect of the present invention, it is preferable that the solid-state image pickup element further comprises a third film with a refractive index lower than that of the second film is provided between the first film and second film.

In the solid-state image pickup element according to an aspect of the present invention, it is preferable that a low refractive index film whose refractive index is 1.2 to 1.5 inclusive and thickness is 150 nm or less of film is arranged as an outermost layer.

By forming the film in the outermost layer, even in the case that the first film, second film, and third film have an anti-reflection function, when its reflectance sways in a ripple depending on an incident wavelength, it is possible not only to make the ripple as small as possible, but also to lower a whole reflectance.

In the solid-state image pickup element according to an aspect of the present invention, it is preferable that the refractive index of the third film is 1.3 to 1.7 inclusive.

In the solid-state image pickup element according to an aspect of the present invention, it is preferable that the third film includes one material selected from a group comprising magnesium fluoride, silicon oxide, silicon nitride, and nitride oxide silicon.

In the solid-state image pickup element according to an aspect of the present invention, it is preferable that film thickness of the third film is 30 nm to 200 nm inclusive.

In order to achieve the object, according to an aspect of the present invention, a solid-state image pickup element comprises a semiconductor substrate, a light receiving section formed on the semiconductor substrate, an electric charge transfer section formed on the semiconductor substrate and transfers electric charges generated in the light receiving section, and an anti-reflection film formed above the light receiving section, and at least one layer constructing the anti-reflection film is produced by a coating method.

According to the aspect of the present invention, it is possible to form an anti-reflection film inexpensively by producing the at least one of layers constructing the anti-reflection film by the coating method. In consequence, it is possible to produce the solid-state image pickup element inexpensively.

In the solid-state image pickup element according to an aspect of the present invention, in order to enhance quantum efficiency, it is preferable that the anti-reflection film has film thickness at 10 nm to 100 nm and comprises a single layer, or two or more layers.

In the solid-state image pickup element according to an aspect of the present invention, the anti-reflection film can be produced by the coating method which enables to easily control refractive index of the anti-reflection film and is inexpensive in comparison with vacuum process. It is preferable that the one layer the anti-reflection film is produced by a sol gel method, or by coating and drying a solution including inorganic oxide particulates at 10 nm or less of diameter, or by coating and curing a UV cure resin including inorganic oxide particulates at 10 nm or less of diameter.

In the solid-state image pickup element according to an aspect of the present invention, it is preferable that coating of the one layer the anti-reflection film is performed by any one or combination of dip coating, spray coating, or spin coating.

The solid-state image pickup element can be inexpensively produced by applying these coating methods.

In the solid-state image pickup element according to an aspect of the present invention, it is preferable that the one film the anti-reflection film is insoluble in alkylbenzene sulfonic acid, propylene glycol monomethyl ether acetate, methyl ethyl ketone, monoethanolamine, dimethyl sulfoxide, N-methyl prolidon, ethylene carbonate, tetramethylammonium hydroxide, and acetone.

This is so as to prevent the anti-reflection film from dissolving in a solvent, used at these steps, in the steps of photolithography, performed after formation of the anti-reflection film and polymer structure of the anti-reflection film from changing.

In the solid-state image pickup element of the present invention, it is preferable that the one film includes one material selected from a group comprising silicon nitride, cerium oxide, zirconium oxide, yttrium oxide, hafnium oxide, tantalum oxide, titanium nitride, magnesium fluoride, silicon oxide, nitride oxide silicon, and titanium oxide. Silicon nitride, silicon oxide, or titanium oxide is more preferable.

In the solid-state image pickup element of the present invention, it is preferable that the light-receiving element receives light out from a face of the semiconductor substrate on which the charge transfer section is formed. In the solid-state image pickup element according to an aspect of the present invention, it is preferable that the light-receiving element receives light out from a face opposite to a face of the semiconductor substrate on which the electric charge transfer section is formed. This specifies a direction where light illuminates in the solid-state image pickup element.

In the solid-state image pickup element according to an aspect of the present invention, in the case that the light-receiving element receives light out from a face opposite to a face of the semiconductor substrate on which the electric charge transfer section is formed, it is preferable that the semiconductor substrate is produced from a SOI wafer.

The SOI wafer comprises a silicon substrate, an embedded oxide film, and an epitaxial silicon layer. Since a photoelectric conversion section formed in the epitaxial silicon layer is used in the back illuminated solid-state image pickup element, the silicon substrate is removed by etching. The embedded oxide film is used effectively as a stopper film during the etching of the silicon substrate.

According to an aspect of the present invention, it is preferable that the solid-state image pickup element further comprises a color filter and/or a microlens.

This is because a function as a solid-state image pickup element is improved by comprising the color filter and/or microlens.

According to the aspects of the present invention, since a first film with a high refractive index and a second film with a low refractive index, each of which has at least one layer respectively, are adjacently arranged in this order viewing from a semiconductor substrate side on which a light receiving section is formed, it is possible to obtain a solid-state image pickup element which enables to decrease an optical loss of incident light and to improve a photoelectric conversion efficiency.

Since a low refractive index film is arranged in an outermost layer of the solid-state image pickup element, it is possible to reduce a ripple-like loss.

When the silicon oxide film is formed on the semiconductor substrate, it is possible to reduce a reflectance by making its film thickness as thin as possible.

In the solid-state image pickup element according to the aspects of the present invention, it is possible to obtain a solid-state image pickup element which enables to decrease an optical loss of incident light and to improve a photoelectric conversion efficiency by providing a third film with a refractive index lower than that of the second film between the first film and the second film.

According to the aspects of the present invention, it is possible to obtain a solid-state image pickup element with an anti-reflection film produced by a method which is comparatively inexpensive and simple.

### BRIEF DESCRIPTION OF THE DRAWINGS

FIG. 1 is a perspective view showing an external form of a solid-state imaging device according to the present invention;

FIG. 2 is a schematic sectional diagram for describing a part of the solid-state image pickup element according to an embodiment of the present invention;

FIGS. 3A and 3B are schematic sectional diagrams for describing a part of a film stack according to an embodiment of the present invention;

FIG. 4 is a graph showing reflectance characteristics of first and second examples in a light region;

FIG. 5 is a schematic sectional diagram for describing of a part of a film stack according to an embodiment of the present invention;

FIG. 6 is a graph showing wavelength dispersion characteristic of reflectance;

FIG. 7 is a schematic sectional diagram for describing a film stack according to an embodiment of the present invention;

FIG. 8 is a graph showing reflectance characteristic of third to fifth examples in a visible light region;

FIG. 9 is a schematic sectional diagram for describing a solid-state image pickup element according to a second embodiment of the present invention;

FIG. 10 is a schematic sectional diagram for describing a solid-state image pickup element according to a third embodiment of the present invention; and

FIGS. 11A and 11B are schematic sectional diagrams for describing an anti-reflection film according to the embodiment of the present invention.

### DETAILED DESCRIPTION OF THE PREFERRED EMBODIMENTS

Although preferable embodiments of the present invention are describes according to accompanying drawings below, it is possible to perform modifications by many methods without deviating from the scope of the present invention, and to use other embodiments besides these embodiments. Hence, all the modifications of the present invention within the scope are included in the scope of claims.

### [Solid-State Imaging Device]

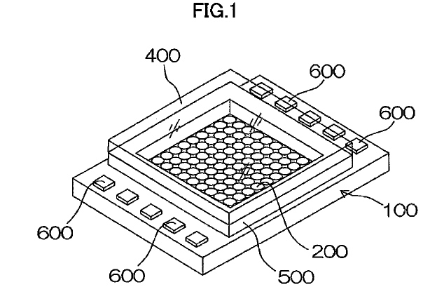

FIG. 1 is a perspective view showing an external form of a solid-state imaging device which relates to an embodiment of the present invention. The solid-state imaging device is constructed of a solid-state image pickup element chip 100 in which solid-state image pickup elements 200 are provided, a frame-shaped spacer 500 which surrounds the solid-state image pickup elements 200 provided in the solid-state image pickup element chip 100, and a cover glass 400 which is installed on a receptacle of the spacer and seals the solid-state image pickup elements. The solid-state image pickup element chip 100 is equipped with two or more pads 600 outside the solid-state image pickup elements 200. It is for wiring with the external.

### [Solid-State Image Pickup Element]

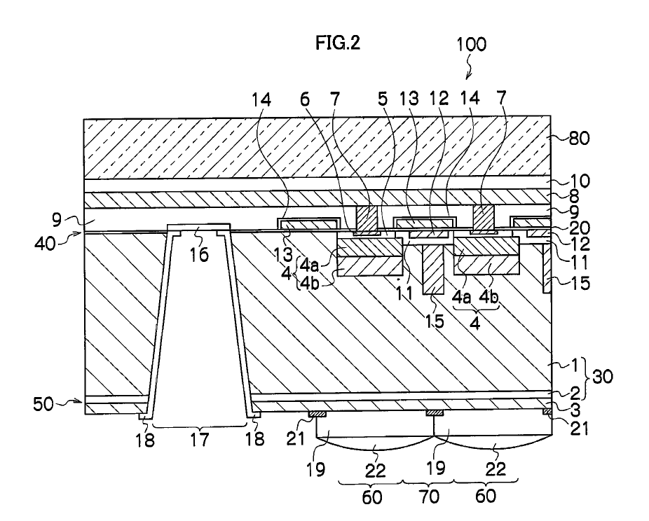

FIG. 2 shows sectional structure of a back illuminated CCD type solid-state image pickup element to which the present invention is applied. The solid-state image pickup element chip 100 is equipped with a p-type semiconductor substrate 30 which has a p-type silicon layer 1, and a p++ type silicon layer 2 in which impurity is higher than that of the p-type silicon layer 1. The p-type semiconductor substrate 30 is equipped with a first surface 40 and a second surface 50 which is an opposite side to the first surface 40. In this specification, the second surface 50 of the p-type semiconductor substrate 30 is called a backside, and the solid-state image pickup element to which a light irradiates out from the second surface 50 is called a back illuminated solid-state image pickup element.

In order to store charges generated in the p-type semiconductor substrate 30 according to incident light, a plurality of n-type impurity diffusion layers 4 are formed in a first surface 40 side of the p-type semiconductor substrate 30. The n-type impurity diffusion layer 4 has two-layer structure of having an n-type impurity diffusion layer 4a and an n-type impurity diffusion layer 4b which are formed in this order viewing from the first surface 40 side. Charges generated in the n-type impurity diffusion layer 4, and charges generated at the time of incident light from the second surface 50 side passing the p-type semiconductor substrate 30 are stored in the n-type impurity diffusion layer 4. The n-type impurity diffusion layer 4 and p-type semiconductor substrate 30 which generate charges in corresponding to the incident light construct a light receiving section 70.

Highly-concentrated p+ type impurity diffusion layers 5 are formed on the respective n-type impurity diffusion layers 4. It is for preventing dark charges generated in the first surface 40 of the p-type semiconductor substrate 30 from being stored in the respective n-type impurity diffusion layers 4. N+ type impurity diffusion layers 6 which are more highly concentrated than the n-type impurity diffusion layers 4 are formed inward into the p-type semiconductor substrate 30 viewing from the first surface 40 side in the respective p+ type impurity diffusion layers 5. Each n+ type impurity diffusion layer 6 functions as an overflow drain for discharging unnecessary charges stored in the n-type impurity diffusion layer 4. Each p+ type impurity diffusion layer 5 functions as an overflow barrier of the overflow drain.

Charge transfer channels 12 are formed in the first surface 40 side of the p-type semiconductor substrate 30 in a position where each n-type impurity diffusion layer 4 and each p+ type impurity diffusion layer 5 are separate. In addition, each p-type impurity diffusion layer 11 whose concentration is lower than that of the p+ type impurity diffusion layer 5 is formed to surround the charge transfer channel 12.

A gate insulating film 20 which is constructed of a silicon oxide film, an ONO (Oxide Nitride Oxide) film, and the like is formed on the first surface 40 of the p-type semiconductor substrate 30, and further, electrodes 13 which are made of polysilicon and the like are formed on the gate insulating film 20. Charges (signal) generated in the light receiving section are transferred by the charge transfer channels 12 and electrodes 13, and CCDs (signal transfer section 70) are constructed. Each surface of the electrodes 13 is covered with an oxide film 14.

In order to prevent charges from leaking into the adjacent n-type impurity diffusion layers 4, element isolation layers 15 are formed between the adjacent n-type impurity diffusion layers 4.

An insulating film 9 made of silicon oxide or the like is formed on the first surface 40 so as to cover the electrodes 13 and oxide films 14. Electrodes 7 are formed through contact holes formed in the insulating film 9 so as to connect to the n+ type impurity diffusion layers 6 electrically. An electrode 8 is provided on the insulating film 9 so as to connect to electrodes 7 electrically. A protective layer 10 is formed on the electrode 8. Furthermore, on the protective layer 10, a support substrate 80 which is made of silicon, glass, or the like is provided by a lamination method such as a surface activation technique.

In order to prevent dark charges, generated in a backside of the p-type semiconductor substrate 30, from moving to the n-type impurity diffusion layers 4, a p++ type silicon layer 2 is provided inside from a backside of the p-type semiconductor substrate 1. A terminal is connected to the p++ type silicon layer 2, and a predetermined voltage can be applied to this terminal. Impurity concentration of the p++ type silicon layer 2 is, for example, 1×10¹⁷/cm³ to 1×10²⁰/cm³.

Aluminum pads 16 are formed on the first surface 40, and are covered by the protective layer 10. In order to expose the aluminum pads 16, through holes 17 are formed in the p-type semiconductor substrate 30. Metal wires (not illustrated) are wire-bonded to exposed surfaces of the aluminum pads 16 through these through holes 17. In addition, lest the metal wires should contact the p-type semiconductor substrate 30 in each through hole 17, insulating layers 18 are formed in a sidewall of each through hole 17.

On the second surface 50 of the p-type semiconductor substrate 30, the film stack 3 is formed with the first film with a high refractive index and the second film with a low refractive index. The first film and the second film have at least one layer respectively, and are adjacently arranged in this order viewing from the semiconductor substrate 30 side. The film stack 3 is fundamentally formed of an insulating film. Hence, it is possible to form the above-described each insulating layer 18 on the sidewall of each through hole 17 with the film stack 3 in the same process. This brings an effect of step omission.

On the film stack 3, two or more color filters 19 are formed. Each of the color filters 19 is constructed to transmit light in different wavelength bands respectively. In order to prevent color mixture, light shielding members 21 are formed between the respective color filters 19. As the light shielding member 21, a material which does not make light transmit, for example, W (tungsten), Mo (molybdenum), or Al (aluminum), or a black filter is used. In order to efficiently guide incident light from a backside to the n-type impurity diffusion layers 4 which are a charge generating region, microlenses 22 are formed on each of the color filters 19.

As a solid-state image pickup element, the back illuminated CCD type solid-state image pickup element is described as an example. It may be any of a front illuminated CCD type solid-state image pickup element and a front illuminated CMOS solid-state image pickup element, and a back illuminated CMOS solid-state image pickup element.

### [Film Stack]

### A. First Embodiment

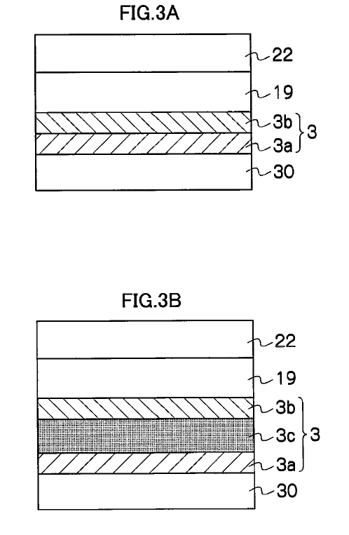

As described above, the film stack 3 of the present invention is formed so that the light receiving sections 60 formed in the semiconductor substrate 30 may be covered. As shown in FIG. 3A, in the film stack 3 with two layer structure, a first film 3a having a high refractive index, and a second film 3b having a low refractive index are provided in this order viewing from the semiconductor substrate 30 side, and further, the color filters 19 and microlenses 22 are formed on the second film 3b. As shown in FIG. 3B, in the film stack 3 with three layer structure, the first film 3a, a third film 3c, and the second film 3b are provided in this order viewing from the semiconductor substrate 30 side, and further, the color filters 19 and microlenses 22 are formed on the second film 3b. Refractive indices of respective layers of the first film 3a, second film 3b, and third film 3c of the film stack 3 according to the embodiment of the present invention have following relationship.
first film 3a>second film 3b>third film 3c
   (1) First Film (3a)

A preferable refractive index range is 1.6 to 2.5 inclusive, and a preferable film thickness range is 10 nm to 100 nm inclusive. In addition, it is preferable that the first film 3a includes at least one material selected from a group comprising silicon nitride, cerium oxide, zirconium oxide, yttrium oxide, hafnium oxide, tantalum oxide, titanium nitride, and titanium oxide.

(2) Second Film (3b)

A preferable refractive index range is 1.3 to 1.9 inclusive, and a preferable film thickness range is 30 nm to 200 nm inclusive. In addition, it is preferable that the second film 3b includes at least one material selected from a group comprising magnesium fluoride, silicon oxide, silicon nitride, nitride oxide silicon, and silicon nitride.

(3) Third Film (3c)

A preferable refractive index range is 1.3 to 1.7 inclusive, and a preferable film thickness range is 30 nm to 200 nm inclusive. In addition, it is preferable that the third film 3c includes at least one material selected from a group comprising magnesium fluoride, silicon oxide, silicon nitride, and nitride oxide silicon.

### B. Second Embodiment

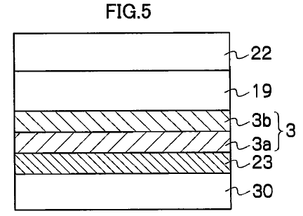

In the first embodiment, the case that a film stack is directly formed on a semiconductor substrate is described. However, in fact, when a semiconductor substrate is processed in two or more production processes, a silicon oxide film may be formed at a certain amount of film thickness on the semiconductor substrate. Hence, when forming a film stack on a semiconductor substrate, as shown in FIG. 5, a silicon oxide film 23, the film stack 3 (the first film 3a and the second film 3b), the color filters 19, and the microlenses 22 are formed in this order viewing from the semiconductor substrate 30 side. A reflectance in optimum combination was investigated by setting film thickness of the first film 3a and second film 3b within a range of 10 to 200 nm, and changing a refractive index within 1.46 to 2.5.

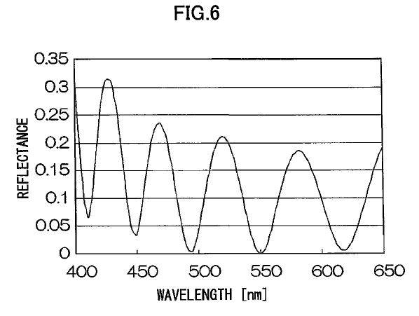

It was confirmed that, in construction that the two layers of film stack 3 was formed on the silicon oxide film 23 on the semiconductor substrate 30, as a graph of a wavelength dispersion characteristic of the reflectance shown in FIG. 6, the reflectance changed in a shape of a ripple depending on wavelength of radiated light. In consequence of evaluating an average reflectance (wavelength: 400 to 650 nm), even a combination with a lowest reflectance had 12%. At this time, the refractive index of the first film 3a was 2.0 to 2.5, and the refractive index of the second film 3b was 1.46 to 1.57.

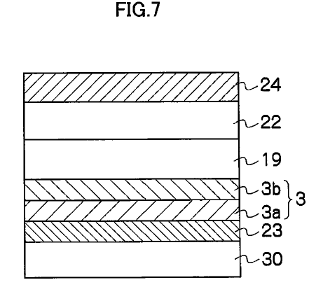

When investigating ripple-like loss reduction of the wavelength dispersion characteristic of the reflectance, it was confirmed that it was effective to provide a low refractive index film with a comparatively low refractive index in an outermost layer of the solid-state image pickup element in addition to the film stack 3. As shown in FIG. 7, its construction was that the silicon oxide film 23, film stack 3, color filters 19, microlenses 22, and low refractive index film 24 are formed in this order (sequentially) viewing from the semiconductor substrate 30 side. As for the low refractive index film 24, it is preferable that a refractive index is 1.5 or less. It is because a ripple-like loss can be reduced. In addition, although FIG. 7 showed the example in which the low refractive index film 24 was formed on the microlenses 22, the microlenses 22 of the outermost layer of the solid-state image pickup element can also serve as the low refractive index film 24. When the solid-state image pickup element is not equipped with the microlenses 22, the low refractive index film 24 may be provided on the color filters 19, or the color filters 19 may serve as the low refractive index film 24.

Next, when relationship between the silicon oxide film 23 on the semiconductor substrate 30 and the reflectance of the film stack 3 was investigated, it was confirmed that it was preferable that the silicon oxide film 23 was 100 nm or less, and was as thinner as possible. Regardless of thickness of the silicon oxide film 23, so long as adjacently arranging the first film 3a with a high refractive index and the second film 3b with a low refractive index on the semiconductor substrate 30, it was changeless to show a tendency that the reflectance is low and the reflection loss is small.

### [Outermost Layer]

In the solid-state image pickup element according to an embodiment of the present invention, it is preferable that a low refractive index film whose refractive index is 1.2 to 1.5 inclusive and film thickness is 150 nm or less is arranged as an outermost layer.

By forming the film in the outermost layer, also in the case that the first film, second film, and third film have an antireflection function, when its reflectance sways in a ripple depending on an incident wavelength, it is possible not only to make the ripple as small as possible, but also to lower a whole reflectance. It is because, by forming the film in the outermost layer, also in the case that the first film, the second film, and the third film have an anti-reflection function, when its reflectance sways in a ripple depending on an incident wavelength, it is possible not only to make the ripple as small as possible, but also to lower a whole reflectance.

### [Production Method of Film Stack]

The above-described film stack is formed on the light receiving sections of the semiconductor substrate by any one or combination of a physical vapor deposition, chemical vapor deposition, a sputtering method, a sol gel method, and a coating thermal decomposition method with a metal organic acid salt solution. An outline of each method will be described below.

### (1) Physical Vapor Deposition

This is a method of evaporating a thin film material with Joule heat generated by flowing a current in a board produced with heat-resistant metal, such as W (tungsten), Mo (molybdenum), or Ta (tantalum). In the case of high melting point material or an active substance, without using the board as a deposition source, there may be a case of performing vapor deposition by accelerating thermoelectrons, generated by energizing a filament of an electron gun, by a high voltage (4 to 8 kV), and focusing and deflecting an electron beam by a magnetic field to collide the electron beam against and to heat a vapor deposition material.

### (2) Chemical Vapor Deposition

This is a method of making a source material radical and highly reactive to be adsorbed and deposit on a substrate, by giving energy to a gas, including the source material, with heat or light, or making the gas plasma by a high frequency wave.

### (3) Sputtering Method

This is a method of accelerating and colliding positive ions against a target with making the target a cathode while generating Ar+ (argon ion) by discharging between electrodes arranged in a vacuum. Since energy which atoms and molecules sputtering from the target by sputtering have is larger than that of the vapor deposition by double figures, a thin film formed of the sputtering has a large adhesion force with a substrate, high density, and high hardness.

### (4) Sol Gel Method

This is based on a reaction that a metal alkoxide is hydrolyzed and becomes a metal oxide through a polycondensation reaction. This is a method of forming a thin film of an oxide by heating after coating the metal alkoxide by a coating method, such as a spin coating, a flow coating, a dipping method, or a spray method.

### (5) Coating Thermal Decomposition Method of Metal Organic Acid Salt Solution

This is based on a reaction that a metal organic acid salt solution is hydrolyzed and becomes a metal oxide through a polycondensation reaction. Process after coating is the same as that of the sol gel method.

After providing the film stack 3, color filters 19, and microlenses 22 on the semiconductor substrate 30 on which a light receiving sections are formed, a transmittance was evaluated. A first example shows an experimental result of the film stack with two-layer structure, and a second example shows an experimental result of the film stack with three layer structure. As an evaluation, transmittances were measured with a spectrophotometer. In addition, the present invention is not limited to these examples.

### Example 1

With letting a semiconductor substrate, which is made of silicon, be a substrate, the film stack with two layer structure shown in Table 1, color filters, and microlenses were provided. At that time, adjustment was performed to let synthetic admittance of a lower layer and its next upper layer gets close to 1. This is because the reflectance becomes low as difference between incidence medium admittance (in case of air: 1) and the synthetic admittance is small.

TABLE 1

| | Composition | Refractive index | Thickness (nm) |
|---|---|---|---|
| Microlens | | 1.56 | 405 |
| Color filter | | 1.65 | 815 |
| Second film | SiN | 1.9 | 30 |
| First film | TiOx | 2.5 | 50 |
| Substrate | Silicon | 4.11 | |

### Example 2

With letting a semiconductor substrate, which is made of silicon, be a substrate, the film stack with three layer structure shown in Table 2, color filters, and microlenses were provided.

TABLE 2

| | Composition | Refractive index | Thickness (nm) |
|---|---|---|---|
| Microlens | | 1.56 | 405 |
| Color filter | | 1.65 | 815 |
| Second film | SiN | 1.9 | 30 |
| Third film | SiO2 | 1.46 | 190 |
| First film | TiOx | 2.5 | 50 |
| Substrate | Silicon | 4.11 | |

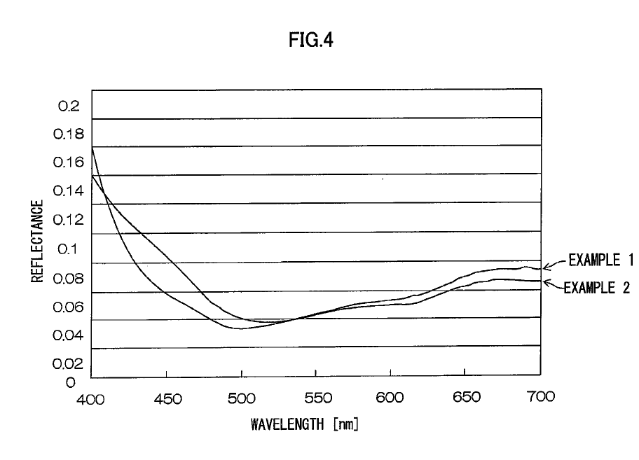

FIG. 4 shows a result of giving equalizing processing in a fixed wavelength band to the reflectance characteristics of the film stacks in the first and second examples in a visible light region. As seen in FIG. 4, since the reflectances of the film stacks to which the present invention was applied were low, enhancement in anti-reflection efficiency could be confirmed. The average reflectance of the first example is 6.78%, and the average reflectance of the second example 2 is 5.29%.

### Examples 3 to 5

As shown in FIG. 5, in a third example, the silicon oxide film 23 (20 nm and 30 nm), film stack 3 with two layer structure (film thickness of first film 3a: 10 to 200 nm, film thickness of second film 3b: 10 to 200 nm), color filters 19 (800 nm), and microlenses 22 (500 nm) were provided on the semiconductor substrate 30.

In a fourth example, as shown in FIG. 7, with letting the semiconductor substrate 30 be a substrate, the silicon oxide film 23 (20 nm and 30 nm), film stack (film thickness of the first film 3a: 10 to 200 nm, film thickness of the second film 3b: 10 to 200 nm) with two layer structure, color filters 19 (800 nm), microlenses 22 (500 nm), and low refractive index film 24 (90 nm) with a refractive index of 1.41 were formed on the semiconductor substrate 30. In a fifth example, differently from the fourth example, a low refractive index film (90 nm) with a refractive index of 1.3 was provided instead of the low refractive index film (90 nm) with the refractive index of 1.41.

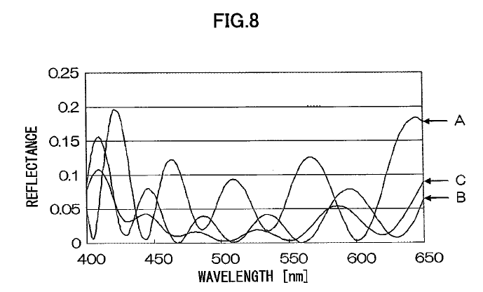

FIG. 8 is a graph showing relationship between the low refractive index film and the reflectance. FIG. 8 shows the wavelength dispersion characteristic of reflectance for each example. A shows the reflectance of the third example, B shows that of the fourth example, and C shows that of the fifth example. Apparently from FIG. 8, it could be confirmed that a ripple-like loss decreased by forming a low refractive index layer on the microlenses. It could be confirmed from the graph that the average reflectance decreased from 8% to 4%.

In addition, when thinning film thickness of the silicon oxide film from 30 nm to 20 nm in the third example, although the first film 3a and second film 3b of the film stack 3 were the same extent, it could be confirmed that the average reflectance to the incident wavelength of 400 to 650 nm decreased from 8% to 10%, to 6% to 8%.

As seen from the test result, according to the embodiment of the present invention, it is possible to obtain a solid-state image pickup element equipped with a film stack which can enhance the anti-reflection efficiency and prevent a loss of incident light to achieve enhancement in the photoelectric conversion efficiency by forming a film stack with two layer structure or three layer structure on a semiconductor substrate. In addition, in a semiconductor substrate on which a silicon oxide film is formed, by thinning the silicon oxide film and/or providing a low refractive index film in an outermost layer in addition to the film stack, it becomes possible to further lower the reflectance and to reduce a ripple-like loss.

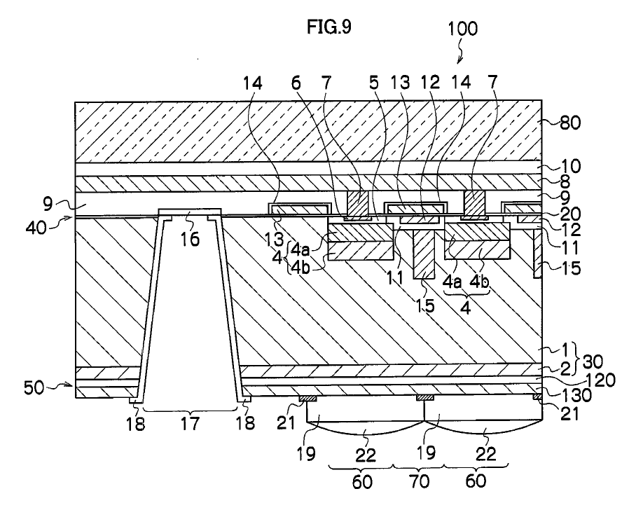

FIG. 9 shows section structure of another back illuminated CCD type solid-state image pickup element to which the present invention is applied. The solid-state image pickup element chip 100 is equipped with a p-type semiconductor substrate 30 which has a p-type silicon layer 1, and a p++ type silicon layer 2 in which impurity is higher than that of the p-type silicon layer 1. The p-type semiconductor substrate 30 is equipped with a first surface 40 and a second surface 50 which is an opposite side to the first surface 40. In this specification, the second surface 50 of the p-type semiconductor substrate 30 is called a backside, and the solid-state image pickup element which is illuminated by a light out from the second surface 50 is called a back illuminated solid-state image pickup element.

In order to store charges generated in the p-type semiconductor substrate 30 according to incident light, a plurality of n-type impurity diffusion layers 4 are formed in a first surface 40 side of the p-type semiconductor substrate 30. Each of the n-type impurity diffusion layers 4 has two-layer structure of having an n-type impurity diffusion layer 4a and an n-type impurity diffusion layer 4b which are formed in this order from the first surface 40 side. Charges generated in each n-type impurity diffusion layer 4, and charges generated at the time of incident light from the second surface 50 side passing the p-type semiconductor substrate 30 are stored in each n-type impurity diffusion layer 4. The n-type impurity diffusion layers 4 and p-type semiconductor substrate 30 which generate charges with corresponding to incident light construct light receiving sections 70.

Highly-concentrated p+ type impurity diffusion layers 5 are formed on the respective n-type impurity diffusion layers 4. It is for preventing that dark charges generated in the first surface 40 of the p-type semiconductor substrate 30 are stored in the respective n-type impurity diffusion layers 4. N+ type impurity diffusion layers 6 which is more highly concentrated than the n-type impurity diffusion layers 4 are formed inward into the p-type semiconductor substrate 30 viewing from the first surface 40 side in the respective p+ type impurity diffusion layers 5. Each n+ type impurity diffusion layer 6 functions as an overflow drain for discharging unnecessary charges stored in each n-type impurity diffusion layer 4. Each p+ type impurity diffusion layer 5 functions as an overflow barrier of the overflow drain.

Charge transfer channels 12 are formed in the first surface 40 side of the p-type semiconductor substrate 30 in positions where they come between n-type impurity diffusion layers 4 and between p+ type impurity diffusion layers 5. In addition, p-type impurity diffusion layers 11 whose concentration is lower than that of the p+ type impurity diffusion layers 5 are formed to surround the charge transfer channel 12.

A gate insulating film 20 which is constructed of a silicon oxide film, an ONO (Oxide Nitride Oxide) film, and the like is formed on the first surface 40 of the p-type semiconductor substrate 30, and further, electrodes 13 which are made of polysilicon and the like are formed on the gate insulating film 20. Charges (signal) generated in the light receiving section is transferred by the charge transfer channels 12 and electrodes 13, and CCDs (signal transfer sections 70) are constructed. Each surface of the electrodes 13 is covered with an oxide film 14.

In order to prevent charges from leaking into the adjacent n-type impurity diffusion layers 4, an element isolation layers 15 are formed between the adjacent n-type impurity diffusion layers 4.

An insulating film 9 made of silicon oxide or the like is formed on the first surface 40 so as to cover the electrodes 13 and oxide films 14. Electrodes 7 are formed through contact holes formed in the insulating film 9 so as to connect to the n+ type impurity diffusion layers 6 electrically. An electrode 8 is provided on the insulating film 9 so as to connect to electrodes 7 electrically. A protective layer 10 is formed on the electrode 8. Furthermore, on the protective layer 10, a support substrate 80 which is made of silicon, glass, or the like is provided by a lamination method such as a surface activation technique.

In order to prevent dark charges, generated in a backside of the p-type semiconductor substrate 30, from moving to the n-type impurity diffusion layers 4, a p++type silicon layer 2 is provided inside viewing from a backside of the p-type semiconductor substrate 1. A terminal is connected to the p++ type silicon layer 2, and a predetermined voltage can be applied to this terminal. Impurity concentration of the p++ type silicon layer 2 is, for example, 1×10¹⁷/cm³ to 1×10²⁰/cm³.

Aluminum pads 16 are formed on the first surface 40, and are covered by the protective layer 10. In order to expose the aluminum pads 16, through holes 17 are formed in the p-type semiconductor substrate 30. Metal wires (not illustrated) are wire-bonded to exposure surfaces of the aluminum pads 16 through these through holes 17. In addition, lest the metal wires should contact the p-type semiconductor substrate 30 in the through holes 17, insulating layers 18 are formed in a sidewall of the through holes 17.

On the second surface 50 of the p-type semiconductor substrate 1, an insulating film 2 which is constructed of silicon oxide transparent to incident light is formed. In a back illuminated solid-state image pickup element 100, an insulating film 120 is formed from a SOI (Silicon On Insulator) wafer. The 801 wafer comprises a silicon substrate, an embedded oxide film, and an epitaxial silicon layer. Since a photoelectric conversion section formed in the epitaxial silicon layer is used in the back illuminated solid-state image pickup element, the silicon substrate is removed by etching with an alkali-based etchant. The embedded oxide film is used effectively as a stopper film during the etching of the silicon substrate. After removing the silicon substrate, the embedded oxide film used as a stopper film is not removed, but is used as the insulating film 2.

An anti-reflection film 130 which is produced by a coating method is formed on the insulating film 120. The anti-reflection film 130 comprises a single film or two or more films whose refractive index and film thickness are selected suitably in consideration of an anti-reflection rate.

Since the anti-reflection film 130 is composed of an insulating film, the insulating layers 18 in sidewall of the through holes can be formed in the same process as that of the anti-reflection film 130. This brings an effect of step omission.

On the anti-reflection film 130, two or more color filters 19 are formed. The color filters 19 are constructed so as to transmit light in different wavelength bands respectively. In order to prevent color mixture, light shielding members 21 are formed between the respective color filters 19. As the light shielding member 21, a material which does not make light transmit, for example, W (tungsten), Mo (molybdenum), or Al (aluminum), or a black filter is used. In order to efficiently guide incident light from a backside to the n-type impurity diffusion layers 4 which are a charge generating region, microlenses 22 are formed on each of the color filters 19.

In the present invention, it is important that the anti-reflection film 130 is insoluble in alkylbenzene sulfonic acid, propylene glycol monomethyl ether acetate (PGMEA), methyl ethyl ketone (MEK), monoethanolamine (MEA), dimethyl sulfoxide (DMSO), N-methyl prolidon (NMP), ethylene carbonate (EC), tetramethylammonium hydroxide (DMSO), and acetone.

In the solid-state image pickup element 100, after forming the anti-reflection film 130, the color filters, microlenses, a light shading film, and the like are formed by a photolithography method. Generally, in the photolithography method, a solvent is used as resist stripping liquid. It is because, when the anti-reflection film 130 is dissolved by the solvent, polymer structure of the anti-reflection film 130 changes, and a characteristic of the film, in particular a refractive index changes, and hence, there is a possibility of not obtaining a predetermined anti-reflection effect.

As a solid-state image pickup element, the back illuminated CCD type solid-state image pickup element is described as an example. It may be any of a front illuminated CCD type solid-state image pickup element and a front illuminated CMOS solid-state image pickup element, and a back illuminated CMOS solid-state image pickup element.

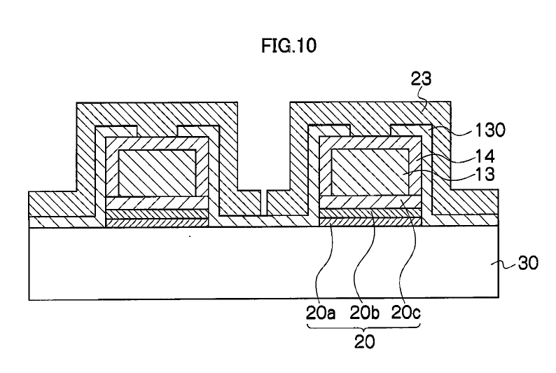

FIG. 10 is a schematically explanatory diagram of the front illuminated type solid-state image pickup element which relates to the present invention. A photodiode and the like are omitted for a simple description. As shown in FIG. 10, the front illuminated solid-state image pickup element is equipped with the semiconductor substrate 30, gate insulating films 20 formed on the semiconductor substrate 30, transfer electrodes 13 formed on each gate insulating film 20, and insulating films 14 covering each transfer electrode 13. Each gate insulating film 20 of this embodiment comprises three layers of a silicon oxide film 20a, a silicon nitride film 20b, and a silicon oxide film 20c. The anti-reflection film 130 is formed by the coating method so as to cover the semiconductor substrate 30 and insulating film 14. In the front illuminated solid-state image pickup element the light shading film 23 is formed to cover the transfer electrodes 13.

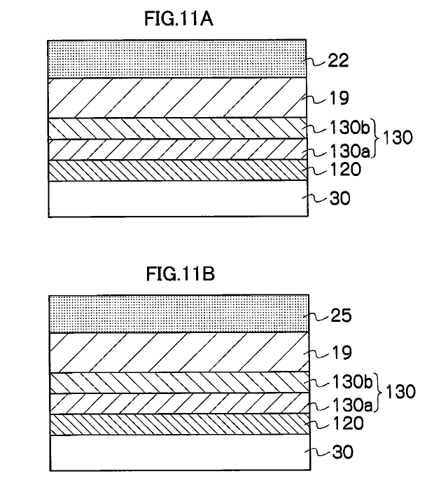

FIGS. 11A and 11B show construction of the anti-reflection film 130 formed in the back illuminated solid-state image pickup element 100. FIG. 1 lA shows the solid-state image pickup element equipped with the microlenses, and FIG. 11B shows the solid-state image pickup element equipped with lid glass instead of the microlens.

As shown in FIG. 11A, the semiconductor substrate 30 is equipped with the insulating film 120 which is constructed of a silicon oxide film. Film thickness of the insulating film 120 is 25 nm. The anti-reflection film 130 which is constructed of two-layer film is formed on the insulating film 120 by the coating method. This anti-reflection film 130 comprises a first film 130a with a high refractive index and a second film 130b with a low refractive index, in this order viewing from the semiconductor substrate 30 side. Film thickness of the first film 130a is 40 nm, and its refractive index is 2.0. In addition, film thickness of the second film 130b is 80 nm, and its refractive index is 1.46. The color filters 19 and microlenses 22 are formed on the second film 130b in this order viewing from the semiconductor substrate 30 side.

Next, as shown in FIG. 11B, the semiconductor substrate 30 is equipped with the insulating film 120 which is constructed of a silicon oxide film. Film thickness of the insulating film 120 is 25 nm. The anti-reflection film 130 which is constructed of two-layer film is formed on the insulating film 120 by the coating method. This anti-reflection film 130 comprises a first film 130a with a high refractive index and a second film 130b with a low refractive index, in this order (sequentially) viewing from the semiconductor substrate 30 side. Film thickness of the first film 130a is 40 nm, and its refractive index is 2.0. In addition, film thickness of the second film 130b is 130 nm, and its refractive index is 1.46. On the second film 130b, the color filters 19 and a lid glass 25 whose thickness is 1 mm or more are provided in this order (sequentially) viewing from the semiconductor substrate 30 side.

Although FIGS. 11A and 11B show the construction of the anti-reflection film with two layers, material, refractive indices, film thicknesses, and the number of the layers are selected suitably in order to obtain a predetermined antireflection rate, and the anti-reflection film is formed on a semiconductor substrate.

### [Coating Method of Anti-Reflection Film]

According to an embodiment of the present invention, an anti-reflection film is formed by the coating method. A sol gel method, coating and drying a solution including inorganic oxide particulates at 10 nm or less of diameter, or coating and curing a UV cure resin including inorganic oxide particulates at 10 nm or less of diameter, which are preferably used in an embodiment of the present invention will be described schematically below.

The sol gel method is based on a reaction that a metal alkoxide is hydrolyzed and becomes a metal oxide through a polycondensation reaction, and is a method of forming a thin film of an oxide by heating after the reaction. A typical reaction formula is shown below. R denotes an alkyl group.

### <Hydrolysis>

Si(OR)₄+H₂O→Si(OR)₃(OH)+ROH

Si(OR)₃(OH)+H₂O→Si(OR)₂(OH)₂+ROH

### <Polycondensation>

Si(OR)₃(OH)+HO—Si(OR)₃→(OR)₃Si—O—(OR)₃+H₂O

Si(OR)₃(OH)+RO—Si(OR)₃→(OR)₃Si—O—(OR)₃+ROH

Materials of the sol gel method are shown in Table 3.

TABLE 3

| | |
|---|---|
| Chemical abbreviation | Chemical formula |

Titanium alkoxide (alkoxytitanium or alkyl
titanate) [General formula: Ti(OR)₄]

| | |
|---|---|
| Tetraisopropyl titanate | [Ti(iOPr)₄] |
| Tetranormalbutyl titanate | [Ti(OBu)₄] |
| Butyl titanate dimer | [(BuO)₃Ti—O—Ti(OBu)₃] |
| Tetraoctyl titanate | [Ti(OOt)₄] |

Titanium chelate (complex) [General formula:
Ti(OR)n (X)4-n X:O Coordination chelate]

| | |
|---|---|
| Titanium acetyl acetonate | [(C₃H₇O)₂Ti(C₅H₇O₂)₂] |
| Titanium octylene glycolate | [(C₈H₁₇O₂)₂Ti(C₈H₁₇O₂)₂] |
| Titanium tetraacetyl acetonate | [Ti(C₅H₇O₂)₄] |
| Titanium ethyl acetoacetate | [(C₃H₇O)₂Ti(C₆H₉O₃)₂] |

Titanium acylate (acyloxy titanate)
[General formula: Ti(OR1)n (OCOR2)4-n]

| | |
|---|---|
| Polyhydroxy titanium stearate | [(Ti(OCOC₁₇H₃₅)—O)n] |

Water-soluble titanium compound

| | |
|---|---|
| Titanium lactate | [(OH)₂Ti(C₃H₃O₂)₂] |
| Titanium triethanol animate | [(C₃H₇O)₂Ti(C₆H₁₄O₃N)₂] |

Next, the coating method by coating and drying a solution including inorganic oxide particulates at 10 nm or less of diameter is a method of curing a film of solution of the inorganic oxide particulates at about normal temperature to 400° C. after coating by the spin coating or the like.

Finally, the coating method by coating and curing a UV cure resin including inorganic oxide particulates at 10 nm or less of diameter is a method of curing a film of resin by radiating a ultraviolet my generated by a low pressure mercury lamp or the like after coating by the spin coating or the like.

A principal component of the ultraviolet curing resin is an acrylic resin or an epoxy resin. As for ultraviolet curing type epoxy resins, there are various additives such as an epoxy resin, an epoxy monomer, an optical cationic initiator, an inorganic minute diameter filler, and so on.

A solvent, a solution, and a resin are coated on a semiconductor substrate also in any one of the above-mentioned methods. Several methods are applied regarding the coating to a semiconductor substrate. For example, a dip coating method, the spray coating method, and spin coating method are suitably used independently, or in combination. Hereafter, each method will be described schematically.

The dip coating method is a method of immersing a sample perpendicularly in predetermined coating liquid, and pulling up it thereafter to make an attached liquid membrane gel in the air (in a vapor phase).

The spray coating method is a method of mixing a solution to a high-speed flow of air, an inert gas, or the like, spraying them to a sample, and performing deposition and coating.

The spin coating method is a method of dripping a solution or sol of a sample to be used as a thin film on a substrate rotating at high speed, and extending it on the substrate by a centrifugal force to form a uniform film.

As mentioned above, in the present invention, since an anti-reflection film is formed by a coating method, it is possible to produce a solid-state image pickup element inexpensively and simply in comparison with a method which needs vacuum processes, such as vapor deposition and sputtering.

What is claimed is:

1. A solid-state image pickup element including a semiconductor substrate, a light receiving section formed on the semiconductor substrate, and a signal transfer section which is formed on the semiconductor substrate and transfers a signal generated in the light receiving section, comprising,
a first film with a high refractive index and a second film with a low refractive index adjacently arranged in this order viewing from the semiconductor side, each of which has at least one layer.

2. The solid-state image pickup element according to claim 1, wherein the refractive index of the first film is 1.6 to 2.5 inclusive, and the refractive index of the second film is 1.3 to 1.9 inclusive.

3. The solid-state image pickup element according to claim 1, wherein the semiconductor substrate comprises a silicon oxide film and film thickness of the silicon oxide film is 100 nm or less.

4. The solid-state image pickup element according to claim 1, wherein the first film includes one material selected from a group comprising silicon nitride, cerium oxide, zirconium oxide, yttrium oxide, hafnium oxide, tantalum oxide, titanium nitride, and titanium oxide.

5. The solid-state image pickup element according to claim 4, wherein the second film includes one material selected from a group comprising magnesium fluoride, silicon oxide, silicon nitride, nitride oxide silicon, and silicon nitride.

6. The solid-state image pickup element according to claim 1, wherein film thickness of the first film is 10 nm to 100 nm inclusive.

7. The solid-state image pickup element according to claim 6, wherein film thickness of the second film is 30 nm to 200 nm inclusive.

8. The solid-state image pickup element according to claim 1, further comprising,
a third film with a refractive index lower than that of the second film between the first film and the second film.

9. The solid-state image pickup element according to claim 1, wherein a low refractive index film whose refractive index is 1.2 to 1.5 inclusive and film thickness is 150 nm or less is placed as an outermost layer.

10. The solid-state image pickup element according to claim 9, wherein the refractive index of the third film is 1.3 to 1.7 inclusive.

11. The solid-state image pickup element according to claim 10, wherein the third film includes one material selected from a group comprising magnesium fluoride, silicon oxide, silicon nitride, and nitride oxide silicon.

12. The solid-state image pickup element according to claim 9, wherein film thickness of the third film is 30 nm to 200 nm inclusive.

13. The solid-state image pickup element according to claim 1, further comprising,
a color filter and/or a microlens.

14. A solid-state image pickup element, comprising a semiconductor substrate, a light receiving section formed on the semiconductor substrate, an electric charge transfer section formed on the semiconductor substrate and transfers electric charges formed on the light receiving section and an anti-reflection film formed above the light receiving section,
wherein at least one layer constructing the anti-reflection film is produced by a coating method.

15. The solid-state image pickup element according to claim 14,
wherein the anti-reflection film has film thickness at 10 nm to 100 nm and comprises a single layer, or two or more layers.

16. The solid-state image pickup element according to claim 15,
wherein one layer of the anti-reflection film is produced by a sol gel method, by coating and drying a solution including inorganic oxide particulates at 10 nm or less of diameter, or coating and curing a UV cure resin including inorganic oxide particulates at 10 nm or less of diameter.

17. The solid-state image pickup element according to claim 16,
wherein one layer of the anti-reflection film is coated by any one or combination of dip coating, spray coating, or spin coating.

18. The solid-state image pickup element according to claim 17,
wherein one layer of the anti-reflection film is insoluble in alkylbenzene sulfonic acid, propylene glycol monomethyl ether acetate, methyl ethyl ketone, monoethanolamine, dimethyl sulfoxide, N-methyl prolidon, ethylene carbonate, tetramethylammonium hydroxide, and acetone.

19. The solid-state image pickup element according to claim 14,
wherein one layer of the anti-reflection film includes one material selected from a group comprising silicon nitride, cerium oxide, zirconium oxide, yttrium oxide, hafnium oxide, tantalum oxide, titanium nitride, magnesium fluoride, silicon oxide, nitride oxide silicon, and titanium oxide.

20. The solid-state image pickup element according to claim 14,
wherein the light-receiving element receives light out from a face of the semiconductor substrate on which the charge transfer section is formed.

21. The solid-state image pickup element according to claim 14,
wherein the light-receiving element receives light out from a face opposite to a face of the semiconductor substrate on which the charge transfer section is formed.

22. The solid-state image pickup element according to claim 21,
wherein the semiconductor substrate is produced from a SOI wafer.

23. The solid-state image pickup element according to claim 14, further comprising a color filter and/or a microlens.
